(19) United States
(12) Patent Application Publication
(10) Pub. No.: US 2009/0243594 A1
(43) Pub. Date: Oct. 1, 2009

(54) METHOD AND DEVICE FOR CHARACTERIZATION OF A MAGNETIC FIELD APPLIED TO A MAGNETIC SENSOR

(75) Inventor: Josephus Arnoldus Henricus Maria Kahlman, Eindhoven (NL)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS, N.V., EINDHOVEN (NL)

(21) Appl. No.: 11/721,573

(22) PCT Filed: Dec. 20, 2005
(86) PCT No.: PCT/IB05/54338

§ 371 Date: Jun. 13, 2007

(30) Foreign Application Priority Data
Dec. 23, 2004 (EP) 04106944.4

(51) Int. Cl. G01R 33/09; G01R 35/00; G01R 33/02

(52) U.S. Cl. 324/202; 324/252; 324/244

(57) ABSTRACT

The present invention provides a magnetic sensor device comprising a plurality of magnetic sensor elements having a sensitive direction. At least one of the magnetic sensor elements (43) is provided with a flux-guide (44) for concentrating onto the sensor element in its sensitive direction a magnetic field applied to the magnetic sensor device. The applied magnetic field is thus bent into the sensitive direction of the magnetic sensor element by the flux-guide. In that way, the field strength and/or orientation of the applied magnetic field can be measured in the absence of magnetic particles. This may be used for, for example, calibration of magnetic sensor devices.

The present invention relates to a magnetic sensor device for the qualitative and/or quantitative detection or determination of magnetic particles, to a magnetic sensor cell for characterization of a magnetic field applied to a magnetic sensor device and its use, and to a method for characterizing a magnetic field applied to a magnetic sensor device.

Magneto-resistive sensors based on anisotropic magneto-resistance (AMR), giant magneto-resistance (GMR) and tunnel magneto-resistance (TMR) elements are nowadays gaining importance. Besides the known high speed applications such as magnetic hard disk heads and magnetic random access memories (MRAM), new relatively low bandwidth applications appear in the field of molecular diagnostics (MDx), current sensing in IC's, automotive industries, etc.

One example of such low bandwidth applications of magneto-resistive sensors is a biochip. Biochips, also called biosensor chips, biological microchips, gene-chips or DNA chips, consist in their simplest form of a substrate on which a large number of different probe molecules are attached, on well defined regions on the chip, to which molecules or molecule fragments that are to be analyzed can bind if they are perfectly matched. For example, a fragment of a DNA molecule binds to one unique complementary DNA (c-DNA) molecular fragment. The occurrence of a binding reaction can be detected, e.g. by using fluorescent markers that are coupled to the molecules to be analyzed. This provides the ability to analyze small amounts of a large number of different molecules or molecular fragments in parallel, in a short time. One biochip can hold assays for 10-1000 or more different molecular fragments. It is expected that the usefulness of information that can become available from the use of biochips will increase rapidly during the coming decade, as a result of projects such as the Human Genome Project, and follow-up studies on the functions of genes and proteins.

In U.S. Pat. No. 5,981,297 a magneto-resistive biosensor is disclosed. This biosensor is intended for bed-side and point-of-care molecular diagnostic (MDx) applications. Sensitivity, small form-factor, low cost, integration and low power consumption are the key issues.

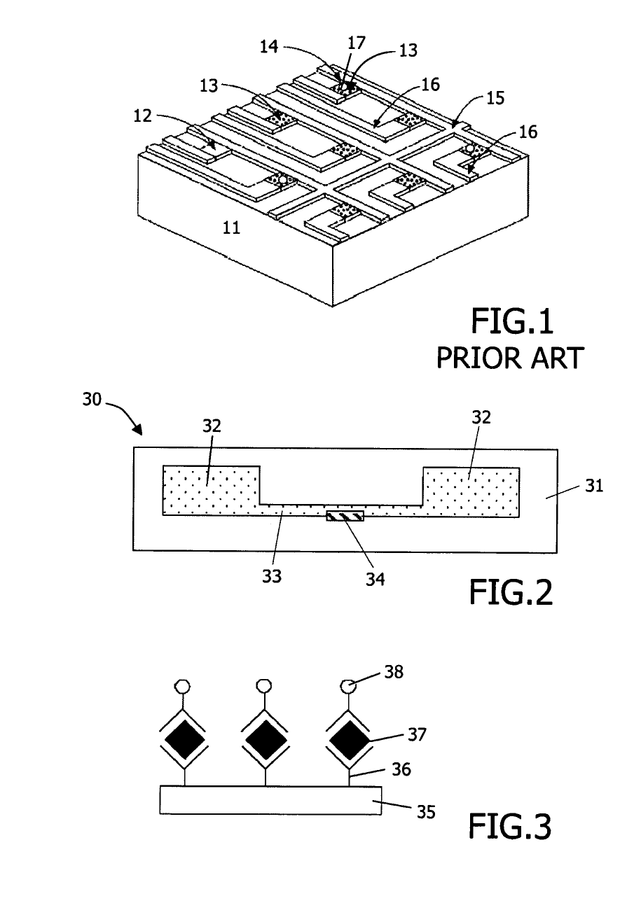

FIG. 1 illustrates a portion of a many-particles-per-element detector as described in U.S. Pat. No. 5,981,297. The magneto-resistive elements measure approximately 20×20 μm and are fabricated by photolithography (or by some other form of microlithography) of a magneto-resistive film deposited on a silicon wafer 11. Reference magneto-resistive elements, such as 12, do not bear binding molecules. Signal magneto-resistive elements bear a coating of covalently attached binding molecules 13, depicted by the small circles in FIG. 1. The signal magneto-resistive element 14 with binding molecules 13 has a magnetic particle 17 attached via a recognition event. To simplify FIG. 1, neither the binding molecules on the particles 17 nor the target molecules are shown. A network of micro-fabricated gold strips 15 carries a bias voltage. Separate micro-fabricated gold strips such as output strips 16 carry an output voltage. The detector of FIG. 1 has one output strip 16 for each magneto-resistive element 12, 14. A thin coating of silicon oxynitride, polymer, diamond-like carbon, or other insulating material covering the magneto-resistive elements 12, 14 and the gold strips 15 and 16 is not shown. The binding molecule coating 13 is applied over the insulating material. The entire detector, containing some 250 magneto-resistive elements, measures approximately 1×1 mm and is capable of detecting 10 target species.

The detector operates as follows. A magnetic field generator (not represented in the drawings) creates a magnetic field that magnetizes the beads or magnetic particles 17. The magnetic field generator can be an electromagnet, an air-cored wire coil, a straight wire, a conductive micro-fabricated trace, or a permanent magnet. Each magnetized bead 17 generates a magnetic field that, due to its presence in the neighbourhood of the magneto-resistive element 12, 14 changes the resistance of the magneto-resistive element 12, 14 to which it is bound. A Wheatstone bridge is used to compare the resistance of the signal element 14 with that of a reference element 12, which is located near the signal element 14 and is identical to it, except that it lacks antibodies or binding molecules 13. The output of the Wheatstone bridge is converted to a digital form; a microprocessor collects the resulting information and determines the total number of magnetized beads 17 on the detector. From this information, and calibration data provided by the manufacturer of the device, the microprocessor can calculate the target species concentration.

In the biosensor described in U.S. Pat. No. 5,981,297, the generated magnetic field is a vertical z-oriented magnetic field, which magnetizes the paramagnetic particles 17, thus generating a horizontal field component. GMR strips on the biosensor detect the presence of these particles 17 by measuring the in-plane horizontal magnetic field component induced by these paramagnetic particles 17. For, for example, calibration purposes, the field strength and the orientation of the external magnetic field with respect to the sensor surface must be known, preferably close to the GMR strip or sensor element. However, the GMR strips on the biosensor are not sensitive in the z-direction. Therefore, in the absence of magnetic particles 17 which have to be detected, the magnetic field applied to biosensor cannot be measured, as the direction of the applied magnetic field does not match with the sensitive direction of the biosensor.

It is an object of the present invention to provide a magnetic sensor device and a corresponding method able to sense a magnetic field applied in a direction different from the sensitive direction of the sensor device.

The above objective is accomplished by a method and device according to the present invention.

Particular and preferred aspects of the invention are set out in the accompanying independent and dependent claims. Features from the dependent claims may be combined with features of the independent claims and with features of other dependent claims as appropriate and not merely as explicitly set out in the claims.

In a first aspect of the invention, a magnetic sensor device, such as, for example, a biosensor, is provided for qualitative or quantitative detection of magnetic particles. The magnetic sensor device comprises a plurality of magnetic sensor elements, each magnetic sensor element having a sensitive direction, wherein at least one of the magnetic sensor elements is associated with a flux-guide for concentrating a magnetic field applied to the magnetic sensor device onto the associated sensor element in the sensitive direction. The magnetic field that is applied to the magnetic sensor device may be, for example, an external magnetic field, i.e. a magnetic field generated by off-chip magnetic field generation means.

The flux-guide is electrically isolated from the magnetic sensor element of the magnetic sensor device and its purpose is for concentrating a magnetic field applied to the magnetic sensor element onto the reference sensor element in the sensitive direction. The flux-guide may, for example, be elongate.

According to an embodiment of the invention, the flux-guide may be positioned such that a signal from the magnetic sensor element is indicative of the field strength of the applied magnetic field.

In one embodiment the magnetic sensor element may lie in a first plane and the flux-guide may lie in a second plane, the first plane and the second plane being positioned substantially parallel with respect to each other, and the flux-guide may show an overlap d with the magnetic sensor element, the overlap d being defined by projection of the magnetic sensor element onto the flux-guide according to a direction substantially perpendicular to the first and the second planes. The overlap d may be between 0 and 100% and may preferably be between 25 and 75%.

In one embodiment according to the invention, the overlap d between the magnetic sensor element and the flux-guide may equal the width w of the magnetic sensor element.

In another embodiment according to the invention, the magnetic sensor element may have a first side and a second side opposite to each other and the flux-guide may extend at least beyond one of the first side or the second side.

In a specific embodiment, the magnetic sensor device may comprise at least two magnetic sensor elements, each being associated with a flux-guide and each magnetic sensor element having a sensitive direction, wherein at least two of the magnetic sensor elements may be positioned with their sensitive directions orthogonal with respect to each other. In this way, more information about the applied magnetic field may be obtained, as the magnetic field strength in two perpendicular directions may be obtained.

According embodiments of the invention, the flux-guide may be formed of a soft magnetic material such as, for example, an iron-silicon alloy, a nickel-iron alloy, a soft ferrite with general formula MOFe₂O₃ or an amorphous, non-crystalline alloy. The amorphous, non-crystalline alloy may, for example, comprises any of iron, nickel and/or cobalt with one or more of boron, carbon, phosphorous or silicon.

In a second aspect according to the invention, a magnetic sensor cell is provided for the characterization of a magnetic field applied to a magnetic sensor device comprising a plurality of magnetic sensor elements. The sensor cell comprises a magnetic sensor element having a sensitive direction and a flux-guide for changing the direction of the applied magnetic field into the sensitive direction of the magnetic sensor element.

An advantage of magnetic sensor cell according to the present invention is that when the strength of the applied magnetic field is characterized during a calibration phase, a certain amount of field inhomogeneity can be allowed because the local magnetic field strength at the immobilisation surface is known.

A further advantage is that there are less stringent constraints to the uniformity of the applied magnetic field because the local field strength can be measured. The magnetic sensor device has a small form factor because of the integrated field strength measurement. Overall accuracy can be improved because of the measurement of the local field strength.

In embodiments according to the present invention, the magnetic sensor element may lie in a first plane and the flux-guide may lie in a second plane, the first plane and the second plane being positioned substantially parallel to each other, and wherein the flux-guide shows an overlap d with the magnetic sensor element, the overlap d being defined by projection of the magnetic sensor element onto the flux-guide according to a direction substantially perpendicular to the first and second planes.

The magnetic sensor element may, for example, be a magneto-resistive sensor element, such as e.g. a GMR, a TMR or a AMR sensor element. The flux-guide may be formed of a soft magnetic material such as, for example, an iron-silicon alloy, a nickel-iron alloy, a soft ferrite with general formula MOFe₂O₃ or an amorphous, non-crystalline alloy. The amorphous, non-crystalline alloy may, for example, comprises any of iron, nickel and/or cobalt with one or more of boron, carbon, phosphorous or silicon.

The sensor cell according to the invention may, for example, be used for the calibration of a magnetic sensor device.

In a further aspect of the present invention a method for the characterization of a magnetic field applied to a magnetic sensor device is provided. The method comprises:
applying a magnetic field to the sensor device, the sensor device comprising at least one magnetic sensor cell comprising a magnetic sensor element having a sensitive direction,
bending the applied magnetic field, i.e. changing the direction of the applied magnetic field, or concentrating a part of the applied magnetic field, into the sensitive direction of the magnetic sensor element, and
sensing a property of the bent magnetic field by the magnetic sensor element.

In embodiments according to the invention, applying a magnetic field may be performed by an off-chip magnetic field generating means, for example, by means of an electromagnet. In other embodiments according to the invention, a combination of off-chip and on-chip magnetic field generating means may be used to apply a magnetic field to the magnetic sensor device.

In embodiments according to the invention, sensing a property of the bent magnetic field may comprise measuring the field strength of the bent magnetic field in at least one direction. In other embodiments, the method may furthermore comprise deriving the field strength of the applied magnetic field from the measured field strength. In one embodiment, sensing a property of the bent magnetic field may comprise measuring the field strength of the bent magnetic field in a first direction and in a second direction, the first and 5 second direction being substantially perpendicular to each other.

In other embodiments according to the invention, the method may furthermore comprise deriving the field strength of the applied magnetic field from the measured field strengths in the first and second directions.

The method according to the invention may, for example, be used for the calibration of a magnetic sensor device.

These and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

FIG. 1 illustrates a biosensor according to the prior art.

FIG. 2 shows a schematic representation of a biosensor device that can be provided with a magnetic sensor device according to embodiments of the present invention.

FIG. 3 shows details of a probe element provided with binding sites able to selectively bind target sample, and magnetic nanoparticles being indirectly bound to the target sample.

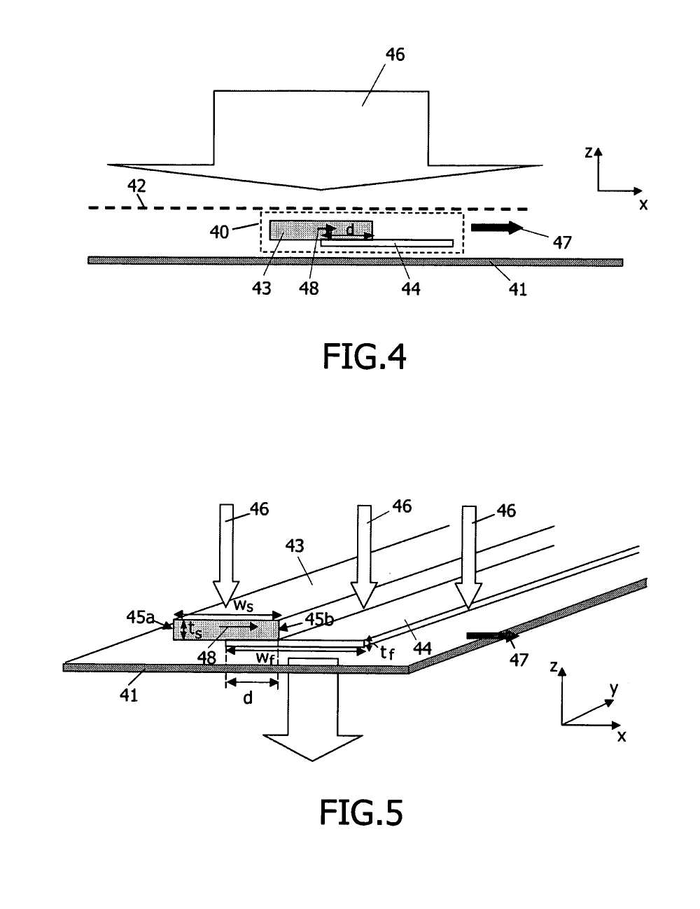

FIG. 4 is a cross-section of a characterization element according to an embodiment of the invention, implemented on a biosensor substrate.

FIG. 5 is a 3D view of the characterization element of FIG. 4.

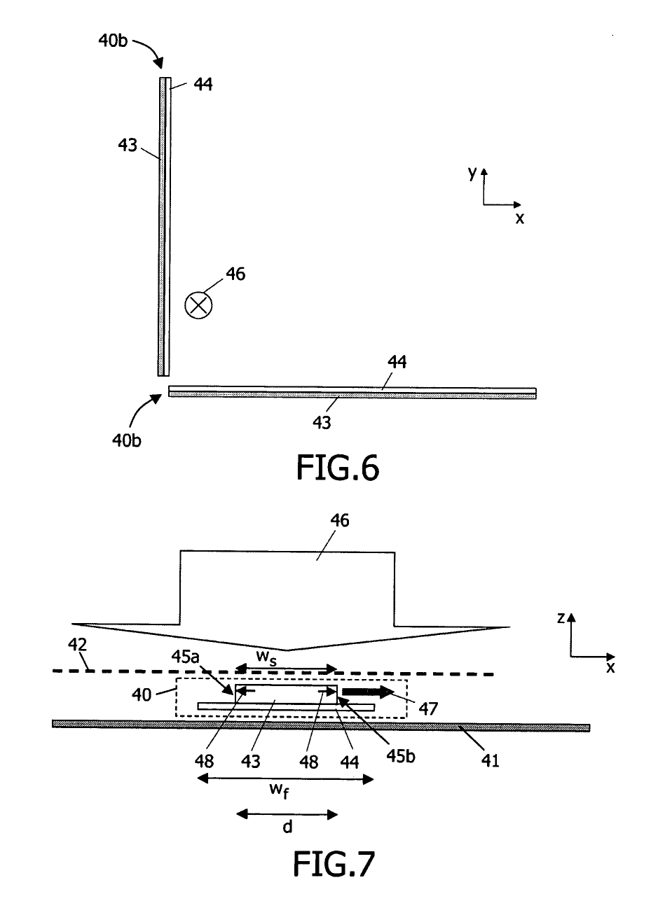

FIG. 6 illustrates a configuration of two characterization elements according to an embodiment of the present invention.

FIG. 7 is a cross-section of a characterization element according to a further embodiment of the present invention implemented on a biosensor substrate.

In the different figures, the same reference signs refer to the same or analogous elements.

The present invention will be described with respect to particular embodiments and with reference to certain drawings but the invention is not limited thereto but only by the claims. Any reference signs in the claims shall not be construed as limiting the scope of the invention. The drawings described are only schematic and are non-limiting. In the drawings, the size of some of the elements may be exaggerated and not drawn on scale for illustrative purposes.

The terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Furthermore, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

Moreover, it is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B. Where an indefinite or definite article is used when referring to a singular noun e.g. “a” or “an”, “the”, this includes a plural of that noun unless something else is specifically stated.

The present invention relates to a magnetic sensor device. The magnetic sensor device may, for example, be used for qualitative or quantitative detection and/or determination of magnetic particles, which can have small dimensions and may for example be nanoparticles. With nanoparticles are meant particles having at least one dimension ranging between 0.1 nm and 1000 nm, preferably between 3 nm and 500 nm and more preferred between 10 nm and 300 nm. The magnetic particles can acquire a magnetic moment due to an applied magnetic field (e.g. they can be paramagnetic) or they can have a permanent magnetic moment. The magnetic particles can be a composite or cluster, e.g. consist of one or more small magnetic particles inside or attached to a non-magnetic material.

The magnetic sensor device according to the present invention comprises a plurality of magnetic sensor elements, each having a sensitive direction. At least one of the magnetic sensor elements is a reference element. Without special measures, and because magnetic sensor elements in a sensor device are not sensitive in a direction perpendicular to the plane of the magnetic sensor device, a generated magnetic field having a magnetic field component in a direction perpendicular to the plane of the sensor element is not accurately detected by the magnetic sensor element in absence of magnetic particles. A magnetic field applied perpendicularly to the plane of the sensor element is not detected at all. However, for particular reasons in, for example, the calibration of magnetic sensor devices such as biosensors, the field strength and the orientation of the applied magnetic field with respect to the sensor surface and preferably close to the magnetic sensor element, i.e., depending on the homogeneity of the magnetic field, within 10 to 1000 μm, preferably within 10 to 100 μm and most preferably within 10 to 50 μm from the magnetic sensor element, must be known.

Therefore, according to the present invention, at least one of the reference elements comprises a flux-guide for concentrating a magnetic field applied to the magnetic sensor device onto the reference sensor element in its sensitive direction. This means that the direction of an externally applied magnetic field is bent into the sensitive direction of the magnetic sensor element. The sensor device according to the present invention may thus be accurately calibrated in the absence of magnetic particles, because providing the flux-guide enables determination of the field strength and orientation of the applied magnetic field.

One example of a magnetic sensor device in which a reference cell comprising a reference magnetic field sensor element provided with a flux-guide according to the invention can be applied is a biosensor device 30 as illustrated in FIG. 2. The biosensor device 30 may comprise a cartridge housing 31, chambers 32 and/or channels 33 for containing the material, e.g. the analyte to be analyzed, and a biochip 34. The biochip 34 is a collection of miniaturized test sites, called micro-arrays, arranged on a solid substrate that permits many tests to be performed at the same time in order to achieve higher throughput and speed. It can be divided into tens to thousands of tiny chambers each containing bioactive molecules, e.g. short DNA strands or probes. In addition to genetic applications (e.g. decoding genes), the biochip 34 may be used in toxicological, protein, and biochemical research, in clinical diagnostics and scientific research to improved disease detection, diagnosis and ultimately prevention.

A biochip 34 comprises a substrate with at its surface at least one, preferably a plurality of probe areas. Each probe area comprises (see FIG. 3) a probe element 35 over at least part of its surface. The probe element 35 is provided with binding sites 36, such as for example including binding molecules or antibodies, able to selectively bind a target sample molecule 37 such as for example a target molecule species or an antigen. Any biologically active molecule that can be coupled to a matrix is of potential use in this application. Examples may be nucleic acids with or without modifications (e.g. DNA, RNA), proteins or peptides with or without modifications (e.g. antibodies, DNA or RNA binding proteins), oligo- or polysaccharides or sugars, small molecules such as inhibitors, ligands, cross-linked as such to a matrix or via a spacer molecule. Magnetic particles 38 may be directly (not represented in the drawings) or indirectly (as in FIG. 3) bound to the target sample molecules 37.

The biosensor device 30 may be adapted to detect magnetic particles 38 in a sample such as a fluid, a liquid, a gas, a visco-elastic medium, a porous medium, a gel or a tissue sample.

The biochip 34 may comprise a substrate and a circuit, e.g. an integrated circuit. The circuit comprises at least one magnetic sensor element and at least one magnetic field generator. The magnetic field generator may for example be an external or off-chip magnetic field generator or may be a combination of an off-chip magnetic field generator and an on-chip magnetic field generator. Magnetic fields generated by an on-chip magnetic field generator are less preferred because they are usually very local and inhomogeneous, which makes the transformation of the measured fields to the value present on the sensor device rather complex. This transformation is determined by the chip-layout of the sensor device and by the currents in the field generating means, for example current wires. Furthermore, such on-chip generated fields produce an in-plane component, so that in most of the cases no flux-guides have to be added to enable the measurement of said fields.

The magnetic sensor element may for example be a magneto-resistive sensor element such as e.g. a GMR, a TMR or an AMR sensor element.

According to a further embodiment of the present invention, an inductive measurement by a horizontal on-chip coil may be performed. The induction voltage generated from an AC external vertically oriented field is a measure for said field. Typically such external fields are rather large (>10 kA/m), so that said field can be easily detected.

The present invention provides at least one reference magnetic sensor element of a magnetic sensor device with a flux-guide, electrically isolated from a magnetic sensor element of the magnetic sensor device, for concentrating a magnetic field applied to the magnetic sensor element onto the reference sensor element in the sensitive direction. The flux-guide is located in proximity of the magnetic sensor element. The flux-guide may preferably be made from a soft magnetic material. Soft magnetic materials are materials that are easily magnetised and demagnetised. They typically have an intrinsic coercivity less than 1000 Am⁻¹. Examples of soft magnetic materials that can be used in the invention are e.g. iron-silicon alloys, nickel-iron alloys, amorphous and non-crystalline alloys which may comprise e.g. iron, nickel and/or cobalt with one or more of boron, carbon, phosphorous or silicon, soft ferrites with general formula MOFe₂O₃ (wherein M is a transition metal such as e.g. nickel, manganese or zinc), and all other suitable soft magnetic materials. The flux-guide is positioned such that it is able to rotate the direction of the applied magnetic field, so as to concentrate the applied magnetic field onto the magnetic sensor element. In that way, the applied magnetic field is bent into the sensitive x-direction of the magnetic sensor element, resulting in an in-plane magnetic flux component, which can be measured by the magnetic sensor element. Hence, the signal from the magnetic sensor element may be indicative for the field strength of the applied magnetic field. In that way, the field strength and/or orientation of the applied magnetic field can be measured.

According to embodiments of the invention, any suitable material which is able to deflect at least part of an applied magnetic field into the in-plane direction of the magnetic sensor element may be used to form the flux-guide. Also, for example, shorted coil windings near a magnetic field element may be used to generate an in-plane component of the magnetic field. In FIG. 4 and FIG. 5, a first embodiment of the present invention is illustrated. FIG. 4 shows a cross-sectional view of a reference sensor element comprising a flux-guide 44, and FIG. 5 shows a perspective view thereof.

The magnetic sensor device in FIG. 4 may comprise a substrate 41 and a circuit e.g. an integrated circuit. In embodiments of the present invention, the term “substrate” may include any underlying material or materials that may be used, or upon which a device, a circuit or an epitaxial layer may be formed. In other alternative embodiments, this “substrate” may include a semiconductor substrate such as e.g. a doped silicon, a gallium arsenide (GaAs), a gallium arsenide phosphide (GaAsP), an indium phosphide (InP), a germanium (Ge), or a silicon germanium (SiGe) substrate. The “substrate” may include for example, an insulating layer such as a SiO₂ or an Si₃N₄ layer in addition to a semiconductor substrate portion. Thus, the term substrate also includes glass, plastic, ceramic, silicon-on-glass, silicon-on sapphire substrates. The term “substrate” is thus used to define generally the elements for layers that underlie a layer or portions of interest. Also, the “substrate” may be any other base on which a layer is formed, for example a glass or metal layer. A measurement surface of part of the sensor device is represented by the dotted line 42 in FIG. 4. For the ease of explanation, the circuit comprising a plurality of magnetic sensor elements is not shown in FIG. 4; only a reference magnetic sensor element is shown.

According to the first embodiment of the present invention, the reference sensor element 43 comprises a flux-guide 44. The flux-guide 44 is electrically isolated from the reference magnetic sensor element 43. The magnetic sensor element 43 may for example be a magneto-resistive sensor element such as e.g. a GMR, TMR or AMR sensor element. In this embodiment, the flux-guide 44 may, for example, have an elongate, i.e. a long and narrow, stripe geometry, but the invention is not limited hereto. For example, in alternative embodiments, the flux-guide 44 may have a substantially square shape, i.e. the width w_{f} of the flux-guide may be substantially the same as the length of the flux-guide, or the flux-guide may have a non-straight lined shape, or the flux-guide may be present at a part of the length of the magneto-resistive element only.

In FIG. 5, a 3D view of the positioning of the flux-guide 44 with respect to the magnetic sensor element 43 is shown. The magnetic sensor element 43 may be positioned in a first plane and the flux-guide 44 may be positioned in a second plane, the first plane being parallel to the second plane but offset from it. In this embodiment, the substrate 41 may be positioned in a third plane and the third plane may also be parallel to the first and second plane. The magnetic sensor element 43 may have a width wₛ of a few μm, for example between 1 and 10 μm and a thickness t, of between 0.3 and 1 μm. The flux-guide 44 may have a width w_{f} of between 1 and 1000 μm and a thickness t_{f} of 0.1 to 10 μm. In the embodiment illustrated, the flux-guide 44 is positioned, at least partially, under the magnetic sensor element 43, i.e. between the magnetic sensor element 43 and the substrate 41, showing an overlap d with the magnetic sensor element 43, the overlap d being defined by projection of the magnetic sensor element 43 onto the flux-guide 44 according to a direction substantially perpendicular to the first and second planes. The overlap d may extend over between 0 and 100%, preferably between 25 and 75%, of the total width wₛ of the magnetic sensor element 43 and may in particular cases (see further) extend over the total width w of the magnetic sensor element 43.

As can be seen from FIG. 5, the magnetic sensor element 43 has a first side 45a and a second side 45b opposite to each other and perpendicular to the plane of the magnetic sensor element 43, and the flux-guide 44 may have a part extending in the second plane beyond the second side 45b. In other embodiments, the flux-guide 44 may also extend beyond the first side 45a or beyond both the first side 45a and the second side 45b.

Important is that in-plane magnetic-resistance unbalance between a first side 45a, for example the left side, and a second side 45b, for example, the right side, of the magnetic sensor element 43 is required to generate the in-plane magnetic field component, e.g. to generate a horizontal magnetic field component from a vertical magnetic field. By increasing the width w_{f} of the flux-guide, an increase of unbalance is introduced as well as an increase of the magnetic field strength that is measured.

According to an aspect of the present invention, the flux-guide 44 is in close proximity to the magnetic sensor element 43 in order to be able to change the direction of the applied magnetic field. The term close proximity relates to the effect on a magnetic field. When applying a magnetic field, which may be an external magnetic field, indicated by arrow 46 in FIG. 4 and FIG. 5 or an internal magnetic field, the direction of this applied magnetic field 46 will be bent by the flux-guide 44 into the sensitive x-direction of the magnetic sensor element 43, indicated by arrow 47 in FIGS. 4 and 5. This results in an in-plane flux component at the level of the magnetic sensor element 43, indicated by arrow 48 in FIGS. 4 and 5, which can then be measured by the magnetic sensor element 43. In that way, the magnetic sensor device can, for example, be accurately calibrated in the absence of magnetic particles by determining the field strength and/or the orientation of the applied magnetic field 46 by means of the at least one reference sensor element.

In a second embodiment according to the present invention, the magnetic sensor device may be provided with at least two reference magnetic sensor cells 40a, 40b, each comprising a magnetic sensor element 43 such as for example a magneto-resistive element (e.g. AMR, TMR or GMR sensor element) and a flux-guide 44. Two of the reference magnetic sensor cells 40a, 40b may be positioned orthogonally with respect to each other, i.e., in the example given, a first magnetic sensor cell 40a may be positioned with the sensitive direction of its magnetic sensor element 43 according to the x-direction and the other magnetic sensor cell 40b may be positioned with the sensitive direction of its magnetic sensor element according to the y-direction (see FIG. 6). By using the reference magnetic sensor cell configuration according to this second embodiment of the invention, more information about the in the z-direction applied magnetic field, indicated by arrow 46, may be obtained. In that way, the field strength in the x- and y-direction is obtained, from which the directional and total amplitude of the applied magnetic field 46 may be derived. The configuration of each reference magnetic sensor cell 40a and 40b may be as described in the first embodiment and as illustrated in FIGS. 4 and 5.

In a further embodiment of the invention, besides calibration the invention may also be used for aligning the applied magnetic field 46 perpendicular to the sensor surface 42 in order not to saturate the other magnetic sensor elements on the sensor substrate 41 which are intended e.g. for bio-sensing. FIG. 7 illustrates a particular embodiment of the present invention. At least one magnetic sensor cell comprises a magnetic sensor element 43 and a flux-guide 44. The flux-guide 44 may be positioned under the magnetic sensor element 43, i.e. between the magnetic sensor element 43 and the substrate 41 and may extend beyond the first side 45a and the second side 45b of the magnetic sensor element 43. In that way, the overlap d between the magnetic sensor element 43 and the flux-guide 44 is equal to the total width w₈ of the magnetic sensor element 43. In this embodiment, maximum overlap d between the magnetic sensor element 43 and the flux-guide 44 is achieved.

In the example given in FIG. 7, a perfect balance exists between the first side 45a, for example, the left side, and a second side 45b, for example, the right side of the magnetic sensor element 43. This is not preferred, as in this case no in-plane magnetic flux component 48 will be generated. However, the magnetic sensor configuration depicted in FIG. 7 is only one example of the present embodiment. This embodiment furthermore includes other sensor device configurations where an unbalance between the first side 45a and the second side 45b of the magnetic sensor element is obtained, in order to allow magnetic measurements to be carried out.

When a high spatial accuracy is required, a plurality of magnetic sensor cells 40 comprising magnetic sensor elements 43 provided with flux-guides 44, as described in any of the above embodiments, may be implemented on a magnetic sensor device such as e.g. a biosensor chip. The magnetic sensor cells 40 may be provided at different positions along the substrate 41 of the magnetic sensor device.

Saturation of magnetic sensor cells 40 with flux-guide 44 can be avoided by scaling down the applied magnetic field during the field characterization measurement. If the applied magnetic field is an external magnetic field 46, as in the examples given, this can easily be implemented by the use of, for example, an electromagnet.

An advantage of the present invention is that when the strength of the applied magnetic field is characterized during a calibration phase, a certain amount of field inhomogeneity can be allowed because the local magnetic field strength at the immobilisation surface is known.

A further advantage is that there are less stringent constraints to the uniformity of the applied magnetic field because the local field strength can be measured. The magnetic sensor device has a small form factor because of the integrated field strength measurement. Overall accuracy can be improved because of the measurement of the local field strength.

It is to be understood that although preferred embodiments, specific constructions and configurations, as well as materials, have been discussed herein for devices according to the present invention, various changes or modifications in form and detail may be made without departing from the scope and spirit of this invention.

1. A magnetic sensor device for qualitative or quantitative detection of magnetic particles, comprising a plurality of magnetic sensor elements (43) each having a sensitive direction, wherein at least one of the magnetic sensor elements (43) is associated with a flux-guide (44) for concentrating a magnetic field (46) applied to the magnetic sensor device onto the associated sensor element in the sensitive direction.

2. A magnetic sensor device according to claim 1, wherein said flux-guide (44) is positioned such that a signal from said at least one of the magnetic sensor elements (43) is indicative of the field strength of the applied magnetic field at the sensor element (43).

3. A magnetic sensor device according to claim 2, the magnetic sensor element (43) lying in a first plane and the flux-guide (44) lying in a second plane, the first plane and the second plane being positioned substantially parallel with respect to each other,
wherein the flux-guide (44) shows an overlap d with said magnetic sensor element (43), the overlap d being defined by projection of the magnetic sensor element (43) onto the flux-guide (44) according to a direction substantially perpendicular to the first and the second planes.

4. A magnetic sensor device according to claim 3, wherein said overlap d between the magnetic sensor element (43) and the flux-guide (44) is between 0 and 100%.

5. A magnetic sensor device according to claim 4, wherein the overlap d between the magnetic sensor element (43) and the flux-guide (44) is between 25 and 75%.

6. A magnetic sensor device according to claim 5, the magnetic sensor element (43) having a first side (45a) and a second side (45b) opposite to each other, wherein the flux-guide (44) extends at least beyond one of said first side (45a) or said second side (45b).

7. A magnetic sensor device according to claim 1, comprising two magnetic sensor elements (43) each being associated with a flux-guide (44), each magnetic sensor element (43) having a sensitive direction, the magnetic sensor elements (43) being positioned with their sensitive directions orthogonal with respect to each other.

8. A magnetic sensor device according to claim 1, wherein said flux-guide (44) is formed of a soft magnetic material.

9. A magnetic sensor device according to claim 1, wherein said flux-guide (44) is elongate.

10. A magnetic sensor device according to claim 1, wherein the magnetic sensor device is a biosensor.

11. A magnetic sensor cell for the characterization of a magnetic field (46) applied to a magnetic sensor device comprising a plurality of magnetic sensor elements (43), the sensor cell comprising:
a magnetic sensor element (43) having a sensitive direction (47), and
a flux-guide (44) for changing the direction of the applied magnetic field (46) into the sensitive direction (47) of the magnetic sensor element (43).

12. A magnetic sensor cell according to claim 11, the magnetic sensor element (43) lying in a first plane and the flux-guide (44) lying in a second plane, the first plane and the second plane being positioned substantially parallel to each other,
wherein the flux-guide (44) shows an overlap d with said magnetic sensor element (43), the overlap d being defined by projection of the magnetic sensor element (43) onto the flux-guide (44) according to a direction substantially perpendicular to the first and second planes.

13. A magnetic sensor cell (40) according to claim 11, wherein said magnetic sensor element (43) is a magneto-resistive sensor element.

14. A magnetic sensor cell (40) according to claim 13, wherein the magneto-resistive element is one of a GMR, a TMR or a AMR sensor element.

15. A magnetic sensor cell (40) according to claim 11, wherein the flux-guide (44) is formed of a soft magnetic material.

16. A method for the characterization of a magnetic field (46) applied to a magnetic sensor device, the method comprising:
applying a magnetic field (46) to said sensor device, the sensor device comprising at least one magnetic sensor cell (40) comprising a magnetic sensor element (43) having a sensitive direction (47),
bending said applied magnetic field (46) into the sensitive direction (47) of the magnetic sensor element (43), and
sensing a property of the bent magnetic field by said magnetic sensor element (43).

17. A method according to claim 16, wherein applying a magnetic field (46) is performed by an off-chip magnetic field generating means.

18. A method according to claim 17, wherein applying a magnetic field (46) is performed by an electromagnet.

19. A method according to claim 16, wherein sensing a property of the bent magnetic field (46) comprises measuring the field strength of the bent magnetic field (46) in at least one direction.

20. A method according to claim 19, furthermore comprising deriving the field strength of the applied magnetic field from the measured field strength.

21. A method according to claim 19, wherein sensing a property of the bent magnetic field (46) comprises measuring the field strength of the bent magnetic field (46) in a first and a second direction, said first and second direction being substantially perpendicular to each other.

22. A method according to claim 21, furthermore comprising deriving the field strength of the applied magnetic field from the measured field strengths in the first and second directions.

23. Use of a magnetic sensor cell (40) according to claim 11 for the calibration of a magnetic sensor device.

24. Use of a method according to claim 16 for the calibration of a magnetic sensor device.
